(19) United States
(12) Patent Application Publication
(10) Pub. No.: US 2017/0133608 A1
(43) Pub. Date: May 11, 2017

(54) METHOD FOR FORMING ORGANIC MONOMOLECULAR FILM AND SURFACE TREATMENT METHOD

(71) Applicant: TOKYO ELECTRON LIMITED, Tokyo (JP)

(72) Inventors: Takashi FUSE, Nirasaki-shi (JP); Tomohito MATSUO, Nirasaki-shi (JP); Hidetoshi KINOSHITA, Nirasaki-shi (JP); Tatsuya FUKASAWA, Nirasaki-shi (JP)

(21) Appl. No.: 15/411,435

(22) Filed: Jan. 20, 2017

Related U.S. Application Data
(63) Continuation of application No. PCT/JP2015/063102, filed on May 1, 2015.

(30) Foreign Application Priority Data
Jul. 24, 2014 (JP) 2014-150833

(51) Int. Cl. H01L 51/05; H01L 51/00

(52) U.S. Cl. CPC H01L 51/0558; H01L 51/0094

(57) ABSTRACT

There is provided a method for forming an organic monomolecular film on a surface of a workpiece with a network structure of Si and O formed in at least a portion of the surface. The method includes: performing a surface treatment on the workpiece such that the surface has a state where bonding sites of an organic monomolecular film material to be used exist at high density; and supplying the organic monomolecular film material to the workpiece subjected to the surface treatment and forming the organic monomolecular film on the surface of the workpiece.

### CROSS-REFERENCE TO RELATED APPLICATION

This application is a Continuation application of PCT International Application No. PCT/JP2015/063102, filed on May 1, 2015, which claimed the benefit of Japan Patent Application No. 2014-150833, filed on Jul. 24, 2014, the entire content of each of which is hereby incorporated by reference.

### TECHNICAL FIELD

The present disclosure relates to a method for forming an organic monomolecular film represented by a self-assembled monolayer film and a surface treatment method for forming an organic monomolecular film.

### BACKGROUND

In recent years, an organic thin film made of an organic compound has been used in a variety of fields. An example of such an organic thin film may include an organic semiconductor film or the like used for an organic semiconductor such as an organic transistor.

As such an organic thin film made of an organic compound, a self-assembled monolayer (SAM) film, which is a self-assembled organic monomolecular film having high orderliness, is known.

A self-assembled monolayer film refers to a monomolecular film obtained by: forming chemical bonds with respect to a surface of a predetermined substrate through the use of organic molecules which have functional groups as terminal groups forming predetermined chemical bonds with respect to the predetermined substrate; and orderly arranging anchored organic molecules through regulations from the surface of the substrate and interaction between the organic molecules.

Such as a self-assembled monolayer film can be used as an organic semiconductor film and is effective for modifying a material surface. For example, this self-assembled monolayer film is being considered to be used to improve electrical characteristics of an organic transistor by modifying a substrate surface of the organic transistor (i.e., by controlling the wettability and lipophilicity of the organic transistor).

Patent Document 1 discloses a method for modifying a surface by forming a self-assembled monolayer film using a silane coupling agent on an SiO₂-based substrate. The self-assembled monolayer film using the silane coupling agent has an alkyl group or a fluorinated alkyl group as an organic functional group and can be used to modify a substrate surface to a water-repellent surface.

In addition, Patent Document 1 states that the self-assembled monolayer film using the silane coupling agent can be formed in very simple ways such as exposing the substrate to a vapor of the silane coupling agent, immersing the substrate in a solution of the silane coupling agent, applying the silane coupling agent onto the substrate, or the like.

In addition, Patent Document 2 discloses a method for forming a self-assembled monolayer film by hydrogen-terminating a surface of a polysilicon layer, supplying organic molecules whose terminals have a double bond of carbon to the hydrogen-terminated surface, and reacting the organic molecules with Si.

However, such an organic monomolecular film is being considered to be used for different applications. For example, this organic monomolecular film may be applied to a contamination preventing film required to be formed at high density.

However, in the method disclosed in Patent Document 1, the formation of the SAM on the SiO₂ substrate requires adsorbing a gaseous or liquid silane coupling agent onto the surface of the substrate and then reacting the silane coupling agent with Si of the substrate. However, the reaction at that time progresses very slowly under the existence of water in the air. This degrades controllability of a film formation, which may result in difficulty in forming a dense SAM.

In addition, in the method disclosed in Patent Document 2, a film may be formed on the hydrogen-terminated Si surface at relatively high density. However, since a reaction is unlikely to occur in a surface of a workpiece having a network structure of silicon (Si) and oxygen (O) such as SiO₂, it is very difficult to form a SAM.

### SUMMARY

Some embodiments of the present disclosure provide a method for forming an organic monomolecular film at high density on a surface of a workpiece with a network structure of Si and O formed in at least a portion of the surface, and a surface treatment method for forming such an organic monomolecular film.

According to one embodiment of the present disclosure, there is provided a method for forming an organic monomolecular film on a surface of a workpiece with a network structure of Si and O formed in at least a portion of the surface, including: performing a surface treatment on the workpiece such that the surface has a state where bonding sites of an organic monomolecular film material to be used exist at high density; and supplying the organic monomolecular film material to the workpiece subjected to the surface treatment and forming the organic monomolecular film on the surface of the workpiece.

According to another embodiment of the present disclosure, there is provided a method for forming an organic monomolecular film on a surface of a workpiece with a network structure of Si and O formed in at least a portion of the surface, including: subjecting the workpiece to a surface treatment such that an Si—H bond is formed on the surface of the workpiece; and forming the organic monomolecular film on the surface of the workpiece by supplying a compound whose terminal has a double bond of C to the workpiece subjected to the surface treatment.

According to another embodiment of the present disclosure, there is provided a method for forming an organic monomolecular film on a surface of a workpiece with a network structure of Si and O formed in at least a portion of the surface, including: subjecting the workpiece to a surface treatment such that an O—H bond and an Si—H bond are formed on the surface of the workpiece; and forming the organic monomolecular film on the surface of the workpiece by supplying a silane coupling agent to the workpiece subjected to the surface treatment.

According to another embodiment of the present disclosure, there is provided a surface treatment method including: prior to forming an organic monomolecular film on a surface of a workpiece with a network structure of Si and O formed in at least a portion of the surface by supplying an organic monomolecular film material to the surface of the workpiece, subjecting the workpiece to a surface treatment such that the surface has a state where bonding sites of an organic monomolecular film material to be used exist at high density.

According to another embodiment of the present disclosure, there is provided a surface treatment method including: prior to forming an organic monomolecular film on a surface of a workpiece with a network structure of Si and O formed in at least a portion of the surface by supplying a compound whose terminal has a double bond of C, as an organic monomolecular film material, to the surface of the workpiece, subjecting the workpiece to a surface treatment such that an Si—H bond is formed on the surface of the workpiece.

According to another embodiment of the present disclosure, there is provided a surface treatment method including: prior to forming an organic monomolecular film on a surface of a workpiece with a network structure of Si and O formed in at least a portion of the surface by supplying a silane coupling agent as an organic monomolecular film material, to the surface of the workpiece, subjecting the workpiece to a surface treatment such that an O—H bond and an Si—H bond are formed on the surface of the workpiece.

According to the present disclosure, it is possible to provide a method for forming an organic monomolecular film at high density on a surface of a workpiece with a network structure of Si and O formed in at least a portion of the surface by subjecting the workpiece to a surface treatment such that the surface has a state where bonding sites of an organic monomolecular film material to be used exist at high density.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a block diagram illustrating an example of an organic monomolecular forming apparatus according to one embodiment of the present disclosure.

FIG. 2 is a sectional view illustrating an example of a surface treating part used in the organic monomolecular forming apparatus according to one embodiment of the present disclosure.

FIG. 3 is a sectional view illustrating an example of an organic monomolecular film forming part used in the organic monomolecular forming apparatus according to one embodiment of the present disclosure.

FIG. 4 is a flow chart illustrating an organic monomolecular film forming method.

FIG. 5 is a schematic view for explaining a state when a surface having a network structure of Si and O is subjected to a surface treatment (etching) with plasma of an Ar/H₂ gas.

FIG. 6 is a schematic view for explaining a surface state after the surface having the network structure of Si and O is subjected to a surface treatment (etching) with plasma of an Ar/H₂ gas.

FIG. 7 is a schematic view for explaining a state when a surface having a network structure of Si and O is subjected to a surface treatment (etching) with plasma of an Ar/H₂/O₂ gas.

FIG. 8 is a schematic view for explaining a surface state after the surface having the network structure of Si and O is subjected to a surface treatment (etching) with plasma of an Ar/H₂/O₂ gas.

FIG. 9 is a view illustrating the vicinity of mass number 30 of a TOF-SIMS mass spectrum obtained by checking a surface state when an SiO₂ substrate is treated or is not treated with plasma of an Ar/H₂ gas through the use of the TOF-SIMS mass spectrum.

FIG. 10 is a view showing results of a wear durability test (SW test) for Samples A and B in Experiment example 2.

FIG. 11 is a view showing results of a wear durability test (SW test) for Samples I, J and K in Experiment example 4.

### DETAILED DESCRIPTION

Embodiments of the present disclosure will now be described in detail with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Organic Monomolecular Film Forming Apparatus>

First, an example of an organic monomolecular film forming apparatus for performing an organic monomolecular film forming method according to one embodiment of the present disclosure will be described.

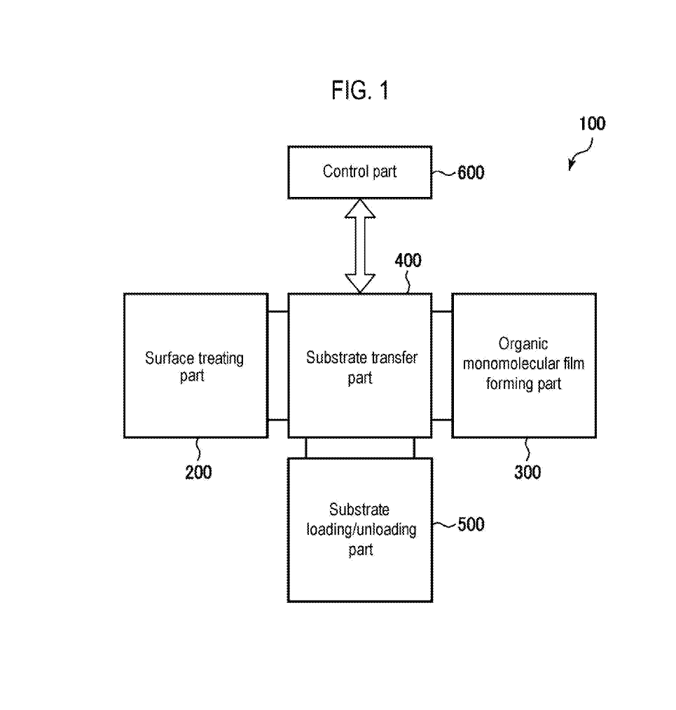

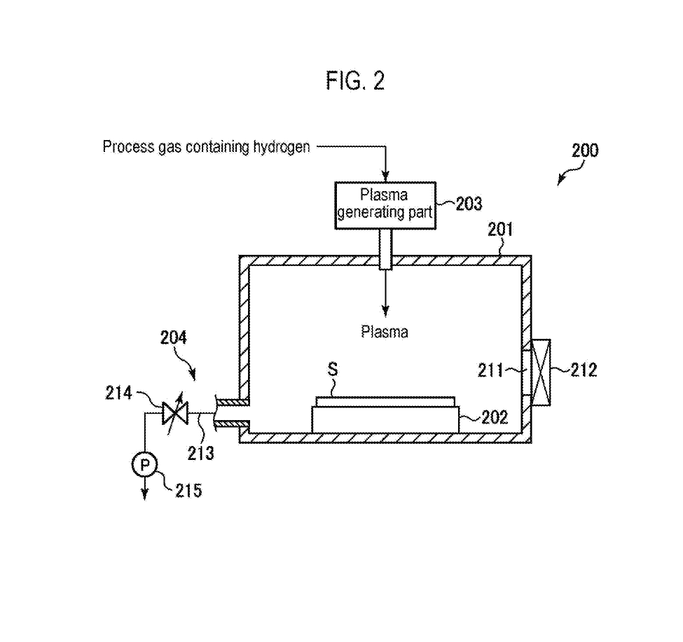

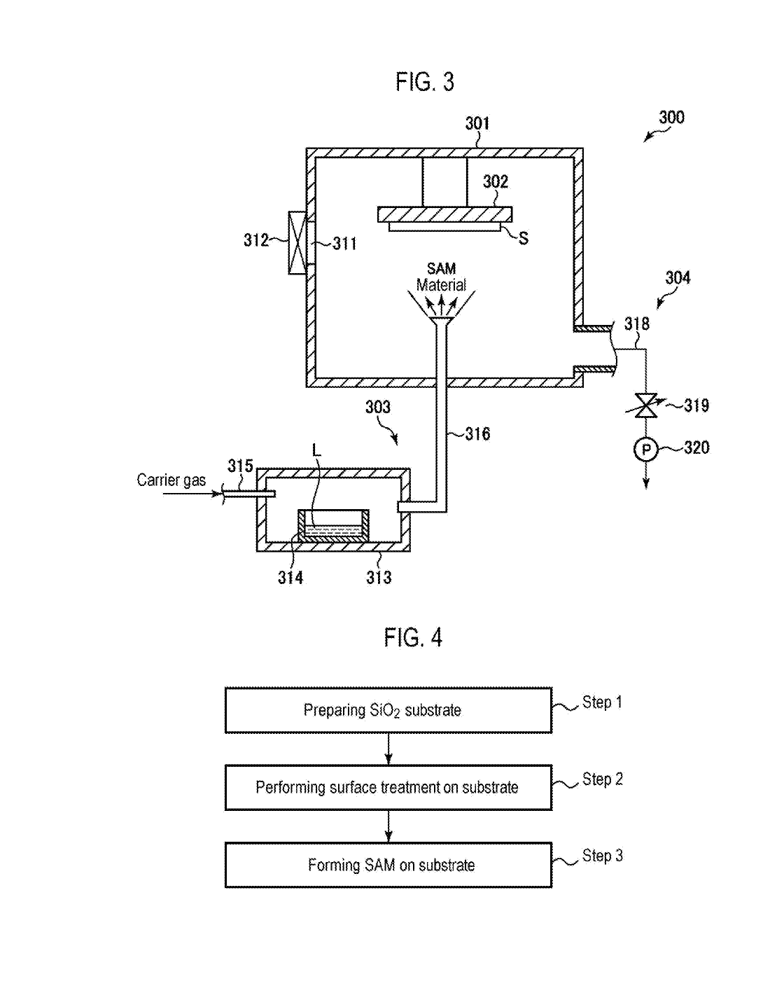

The organic monomolecular film forming apparatus according to one embodiment of the present disclosure is to form a self-assembled monolayer (SAM) film as an organic monomolecular film, on a surface of a workpiece, with a network structure of silicon (Si) and oxygen (O) formed in at least a portion of the surface. A substrate made of SiO₂ (glass) is used as such a workpiece. FIG. 1 is a block diagram of the organic monomolecular forming apparatus for forming the SAM as an organic monomolecular film, on such a substrate. FIG. 2 is a sectional view illustrating an example of a surface treating part 200. FIG. 3 is a sectional view illustrating an example of an organic monomolecular film forming part 300.

As illustrated in FIG. 1, the organic monomolecular film forming apparatus 100 includes a surface treating part 200 configured to perform a surface treatment on a substrate, an organic monomolecular film forming part 300 configured to form an organic monomolecular film on the surface-treated surface, a substrate transfer part 400 configured to transfer the substrate to the surface treating part 200 and the organic monomolecular film forming part 300, a substrate loading/unloading part 500 configured to load and unload the substrate, and a control part 600 configured to control respective components of the organic monomolecular film forming apparatus 100. The organic monomolecular film forming apparatus 100 is configured as a multi-chamber type apparatus. The substrate transfer part 400 includes a transfer chamber kept at vacuum, and a substrate transfer mechanism installed in the transfer chamber. The substrate loading/unloading part 500 includes a substrate holding part and a load lock chamber. The substrate loading/unloading part 500 transfers the substrate held in the substrate holding part to the load lock chamber and loads/unloads the substrate through the load lock chamber.

The surface treating part 200 performs the surface treatment on the substrate such that the surface of the substrate forming the SAM has a state in which a dense SAM is formed of a SAM material (organic monomolecular film material) used. In this example, the surface treating part 200 is configured as a plasma processing apparatus which controls the amount of O and hydrogen (H) in the surface of the substrate S.

As illustrated in FIG. 2, the surface treating part 200 includes a chamber 201, a substrate holder 202 which holds the substrate S in the chamber 201, a plasma generating part 203 which generates plasma and supplies the plasma into the chamber 201, and an exhaust mechanism 204 which evacuates the interior of the chamber 201.

A loading/unloading port 211 which is in communication with the transfer chamber and through which the substrate S is loaded and unloaded, is formed in a side wall of the chamber 201. The loading/unloading port 211 is configured to be opened and closed by a gate valve 212.

A processing gas containing a hydrogen gas is supplied to the plasma generating part 203. The plasma generating part 203 generates a hydrogen-containing plasma with an appropriate way such as a microwave plasma, inductively-coupled plasma, capacitively-coupled plasma or the like and supplies the same into the chamber 201.

The exhaust mechanism 204 includes an exhaust pipe 213 connected to a lower portion of the chamber 201, a pressure control valve 214 installed in the exhaust pipe 213, and a vacuum pump 215 which exhausts the interior of the chamber 201 through the exhaust pipe 213.

The substrate S is held on the substrate holder 202 and the interior of the chamber 201 is kept at a predetermined vacuum pressure. In this state, the hydrogen-containing plasma is supplied from the plasma generating part 203 into the chamber 201 so that the surface of the substrate S is treated with the plasma.

In some embodiments, instead of installing the plasma generating part 203, a parallel flat electrode may be installed inside the chamber 201 to generate an capacitively-coupled plasma in the chamber 201.

As illustrated in FIG. 3, the organic monomolecular film forming part 300 includes a chamber 301 inside which an organic monomolecular film is formed on the substrate S, a substrate holder 302 which holds the substrate inside the chamber 301, a SAM material supply system 303 for supplying a SAM material into the chamber 301, and an exhaust system 304 which exhausts the interior of the chamber 301.

A loading/unloading port 311 which is in communication with the transfer chamber and through which the substrate S is loaded and unloaded, is formed in a side wall of the chamber 301. The loading/unloading port 311 is configured to be opened and closed by a gate valve 312.

The substrate holder 302 is installed in an upper portion of the chamber 301 and holds the substrate S in such a manner that a film formation surface of the substrate S is oriented downward. The substrate holder 302 may include a mechanism configured to heat the substrate S. When the substrate S is subjected to the heating, the substrate S is kept at room temperature.

The SAM material supply system 303 includes a gas generation container 313, a SAM material accommodating vessel 314 installed inside the gas generation container 313, a carrier gas introduction pipe 315 which introduces a carrier gas into the gas generation container 313, and a SAM material gas supply pipe 316 through which a SAM material gas (organic monomolecular material gas) generated inside the gas generation container 313 is supplied into the chamber 301. The SAM material gas supply pipe 316 is installed such that the SAM material gas is discharged from the leading end thereof toward the substrate S. In addition, the SAM material gas obtained by vaporizing a liquid SAM material L accommodated in the SAM material accommodating vessel 314, is carried by the carrier gas so that the SAM material gas is supplied to the vicinity of the substrate S inside the chamber 301 via the SAM material gas supply pipe 316. In a case where the vaporization is insufficient or the SAM material is in a solid state at room temperature, a heater may be installed in the SAM material accommodating vessel 314.

The exhaust system 304 includes an exhaust pipe 318 connected to a lower portion of the chamber 301, a pressure control valve 319 installed in the exhaust pipe 318, and a vacuum pump 320 which exhausts the interior of the chamber 301 through the exhaust pipe 318.

The substrate S whose surface is treated by the surface treating part 200 is held on the substrate holder 302 and the interior of the chamber 301 is kept at a predetermined vacuum pressure. In this state, the SAM material gas is supplied from the SAM material supply system 303 to the vicinity of the substrate S. Thus, the SAM as the organic monomolecular film is formed on the surface of the substrate S.

The control part 600 includes a controller equipped with a microprocessor (computer) for controlling respective components of the organic monomolecular film forming apparatus 100. The controller is configured to control an output, a gas flow rate and a degree of vacuum in the surface treating part 200, a flow rate of the carrier gas and a degree of vacuum in the organic monomolecular film forming part 300, and the like. The controller is connected to a user interface including a keyboard with which an operator inputs commands to manage the organic monomolecular film forming apparatus 100, a display for visually displaying operation situations of the organic monomolecular film forming apparatus 100 and the like. In addition, the controller is connected to a storage part which stores a control program for implementing predetermined operations in a film forming process performed in the organic monomolecular film forming apparatus 100 under the control of the controller, process recipes as control programs for causing respective components of the organic monomolecular film forming apparatus 100 to perform respective predetermined processes according to process conditions, a variety of databases, and the like. The process recipes are stored in an appropriate storage medium in the storage part. Further, as necessary, by calling any process recipe from the storage part and causing the controller to perform the called process recipe, a desired process is performed in the organic monomolecular film forming apparatus 100 under the control of the controller.

### <Organic Monomolecular Film Forming Method>

Next, an organic monomolecular film forming method using the above-described organic monomolecular film forming apparatus 100 will be described. FIG. 4 is a flow chart illustrating the organic monomolecular film forming method according to this embodiment.

As described above, this embodiment involves forming a self-assembled monolayer (SAM) as an organic monomolecular film, on a surface of a workpiece having a network structure of Si and O formed in at least a portion of the surface. A substrate made of SiO₂ (glass) is prepared as such a workpiece (in Step 1).

Thereafter, the substrate S is subjected to a surface treatment (in Step 2). In the surface treatment, first, the substrate S is transferred from the load lock chamber of the substrate loading/unloading part 500 to the surface transfer part 400 shown in FIG. 2 using the substrate transfer mechanism of the substrate transfer part 400. At this time, the gate valve 212 is opened and the substrate S is loaded into the chamber 201 via the loading/unloading port 211. The substrate S is mounted on the substrate holder 202. In this state, while controlling an internal pressure of the chamber 201 by adjusting an exhaust amount with the exhaust mechanism 204, a hydrogen-containing plasma generated inside the plasma generating part 203 is supplied into the chamber 201 so that the surface of the substrate S is plasmarized (plasma-etched).

This surface treatment is to allow the surface of the substrate S to have a state in which a dense SAM is obtained by a SAM material as an organic monomolecular film material used in the SAM material supply system 303.

After the surface treatment, a SAM is formed on the surface-treated substrate S (in Step 3). In forming the SAM, the surface-treated substrate S is unloaded from the chamber 201 by the substrate transfer mechanism of the substrate transfer part 400 and is transferred to the organic monomolecular film forming part 300. At this time, the gate value 312 is opened. The substrate S is loaded into the chamber 301 via the loading/unloading port 311 and is held on the substrate holder 302. In this state, while controlling the internal pressure of the chamber 301 through an adjustment of an exhaust amount by the exhaust system 304, a SAM material gas (organic monomolecular film material gas) obtained by vaporizing a SAM material L is transferred by a carrier gas and is supplied from the SAM material supply system 303 to the vicinity of the substrate S inside the chamber 301. Thus, it is possible to form the dense SAM as the organic monomolecular film on the surface of the substrate S at high density.

Thereafter, the substrate S on which the SAM is formed is unloaded from the chamber 301 by the substrate transfer mechanism of the substrate transfer part 400 and is transferred to the substrate holding part via the load lock chamber of the substrate loading/unloading part 500.

### <Substrate Surface Treatment>

Next, the surface treatment of the substrate, which is particularly important in the above-described organic monomolecular film forming method, will be described in detail.

In the formation of the SAM, a material consisting of organic molecules having bonding sites where a chemical bonding is formed with respect to the surface of the substrate, is used as the SAM material.

A typical example of the SAM material may include a substance (silane coupling agent) consisting of organic molecules expressed by a chemical formula R′—Si(O—R)₃. Where, R′ is a functional group such as an alkyl group or the like, and O—R is a hydrolysable functional group such as a methoxy group or an ethoxy group. This O—R acts as a bonding site. An example of the silane coupling agent may include octamethyltrimethoxysilane (OTS).

In the formation of the SAM using the silane coupling agent, the following reactions (1) and (2), which are called silane coupling, are generated in the surface having a network structure of Si and O, typically, the surface of the SiO₂ (glass) substrate.

R′—Si(O—R)₃+H₂O [symbol] R′—Si(OH)₃+ROH (1)

R′—Si(OH)₃+SiO(surface) [symbol] R′—SiO+Si(surface)+H₂O (2)

With these reactions, a monomolecular functional group (R′) such as an alkyl group or the like adheres to the surface of the SiO₂ substrate so that a physical property of the surface is changed. Such a series of reactions is a two-step reaction including the first reaction (1) of hydrolyzing the SAM material and the second reaction (2) of generating a condensation polymerization with respect to the substrate.

The reactions (1) and (2) can be progressed by adhering the SAM material onto the substrate by exposing the substrate to vapor of the SAM material, immersing the substrate in a solution of the SAM material, or applying the solution of the SAM material onto the substrate, and then by leaving the substrate in air.

These methods allows the SAM material to be adhered on to the substrate, thus progressing the reactions. Thus, these methods are advantageous in reducing costs but causes a very slow reaction. In addition, these methods use water in air, which results in a poor controllability of film formation. Therefore, it is difficult to form the dense SAM on the substrate.

Another example of the SAM material may include a compound which consists of organic molecules expressed by a chemical formula R′—CH═CH₂ and whose terminal has a double bond of C. Where, R′ is a functional group such as an alkyl group or the like. For the SAM material whose terminal has a double bond of C, according to the following chemical formula (3), the double bond is cleaved in the surface of the substrate so that the terminal is bonded to Si.

R′—CH=CH₂+Si—H [symbol] R′—CH₂—CH—Si (3)

This reaction does not use water. Thus, this reaction is good in controllability and facilitates the film formation at high density. However, this reaction requires forming an Si—H bonding in the surface of the substrate. Thus, it is difficult to directly form a film on a surface having a network structure of Si and O, such as the surface of the SiO₂ substrate.

As described above, in the related art, it is difficult to form a dense SAM on a surface having a network structure of Si and O using a typical SAM material.

Therefore, as a result of examining a method for forming a dense SAM with good controllability using a typical SAM material, the present inventors have found that it is effective to perform a surface treatment on a substrate whose surface has a network structure of Si and O such that the surface has a state where bonding sites with a SAM material gas used exist at high density. The surface state where such bonding sites exist at high density corresponds to a surface state where the dense SAM is obtained.

By performing a process using the hydrogen-containing plasma (plasma etching) according to this embodiment as the substrate surface treatment, it is possible to collapse a stable network structure of Si and O in the surface of the substrate, thus adjusting the amount of H and O in the surface. This facilitates the reaction of the surface with a predetermined SAM material.

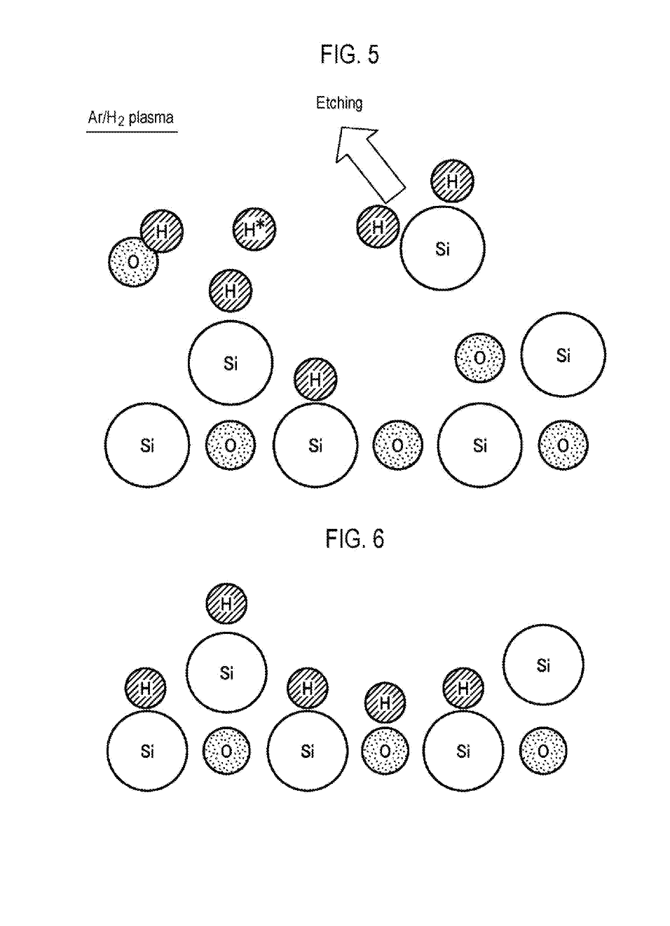

For example, in a case of using, as the hydrogen-containing plasma, plasma containing hydrogen and containing no oxygen, such as plasma generated by a H₂ gas and a rare gas (Ar gas) or plasma generated by the H₂ gas alone, Si of the surface having a network structure of Si and O is etched by hydrogen radicals in plasma, as shown in FIG. 5. Further, O is also separated and the hydrogen radicals penetrate into not only the outermost surface but also the interior of the surface. Therefore, as a result, the surface is brought into a state where a number of Si—H bonds exists, as shown in FIG. 6. The Si—H bonds act as bonding sites of a compound whose terminal has a double bond of C. That is to say, the reaction of the above-described chemical formula (3) progresses in a portion where the Si—H bonds exist, so that the compound whose terminal has the double bond of C is bonded to the portion. Further, the Si—H bonds exist in not only the outermost surface but the interiors of first and second layers under the outermost surface. Thus, the reaction of the chemical formula (3) occurs even in the interiors of first and second layers, which makes it possible to form a dense SAM using a SAM material whose terminal has a double bond of C.

On the other hand, the surface state shown in FIG. 6, which is obtained when the plasma treatment (the plasma etching) is performed using the plasma generated by the H₂ gas and the rare gas (the Ar gas) or the plasma generated by the H₂ gas alone, is brought into a state where a lot of O are separated from the network structure of Si and O by the plasma. In addition, when a silane coupling agent is used as the SAM material, the density of the bonding sites is not sufficient.

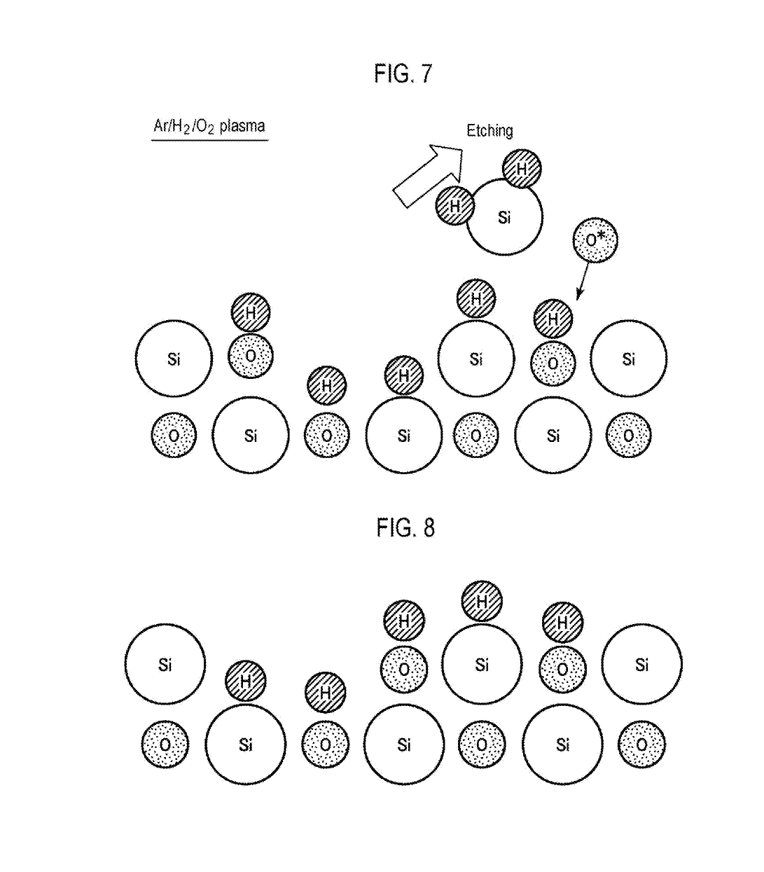

In contrast, when plasma containing both hydrogen and oxygen, such as plasma generated by an H₂ gas, an O₂ gas and a rare gas (Ar gas) or plasma generated by the H₂ gas and the O₂ gas, is used as the hydrogen-containing plasma, as shown in FIG. 7, Si of the surface is etched by hydrogen radicals and O is separated, while O is supplied onto the surface by oxygen radicals in the plasma. For this reason, as shown in FIG. 8, a lot of O—H bonds in addition to the Si—H bonds exist in the outermost surface and the interiors of first and second layers under the outermost surface, thereby making it possible to form bonding sites at high density when the silane coupling agent is used as the SAM material. That is to say, since a portion of the O—H bonds (O—H terminations) acts as bonding sites at which a conventional silane coupling reaction occurs and the Si—H bonds also act as bonding sites of the silane coupling agent. Thus, it is possible to form the bonding sites of the silane coupling agent at high density and form SAM at density further higher than that in the conventional method. However, in the state shown in FIG. 8, since a lot of O exist in the surface and the number of sites where the reaction of the above-described chemical formula (3) occurs is reduced, it is difficult to obtain a dense SAM when a compound whose terminal has a double bod of C is used as the SAM material.

As described above, by performing the surface treatment on the substrate S and properly controlling the amount of H and O in the surface having a network structure of Si and O, it is possible for the surface to be brought into a state where bonding sites of the SAM material are formed at high density according to the SAM material. It is therefore possible to form a dense SAM on the surface having a network structure of Si and O.

In addition, in a case where the plasma treatment is used for the surface treatment of the substrate, a surface cleaning effect based on plasma is obtained. This facilitates the reaction of the surface with the SAM material. For example, when the silane coupling agent is used as the SAM material, it is possible to remove particles of the surface using plasma of an Ar gas or plasma of an H₂ gas. Thus, it is possible to increase the density of SAM more slightly than when the treatment is not used. However, in order to form a dense SAM using the silane coupling agent as the SAM material, it is necessary to use the plasma generated by the H₂ gas and the O₂ gas, as described above.

Although in the above example, the plasma treatment (the plasma etching) has been described to be used as the surface treatment, a wet treatment (a wet etching) may be used as the surface treatment. For the wet treatment, it is possible to control the amount of H and O in the surface by appropriately selecting a process liquid.

A compound whose terminal has a double bond of C may be used as the SAM material as long as Si—H bonds can be formed on a surface having a network structure of Si and O. Accordingly, a hydrogen atomic treatment or a heating treatment in a hydrogen atmosphere (which will be described later) may be used as the surface treatment in addition to the plasma treatment and the wet treatment as described above.

Hydrogen Atomic Treatment

A hydrogen gas is supplied into a vacuum chamber kept in ultrahigh vacuum (1×10⁻⁶ Pa or less) at a pressure of 1×10⁻⁴ Pa. Then, hydrogen molecules are dissociated into hydrogen atoms by thermal electrons or plasma such that the hydrogen atoms are adsorbed on a surface of a substrate.

Heating Treatment in Hydrogen Atmosphere

At the time of evacuation, an internal atmosphere of a chamber is substituted with a hydrogen gas atmosphere by flowing hydrogen as a carrier gas, so that the chamber is kept in a vacuum state of the hydrogen atmosphere. Then, under this hydrogen atmosphere, the substrate is heated to about 400 degrees C. so that hydrogens are adsorbed on the surface of the substrate.

In addition, from the viewpoint of forming a denser SAM, the surface treatment process of Step 2 and the SAM forming process of Step 3 may be repeated plural times. With this configuration, even in a region where no SAM is formed in a first SAM forming process, the SAM is formed by second and subsequent SAM forming processes, thus forming a denser SAM. However, if plasma is used in second and subsequent surface treatment processes, there is a possibility that the SAM formed in the first SAM treatment process is damaged. Therefore, it is preferable to use the wet treatment in the second and subsequent surface treatment processes.

In addition, in a case where a region where bonding sites of a first SAM material exist at high density and a region where bonding sites of a second SAM material exist at high density are formed by the surface treatment process, after the surface treatment process, the first SAM forming process may be performed by supplying the first SAM material, and subsequently, the second SAM forming process may be performed by supplying the second SAM material. As an example, SAM may be formed using a silane coupling agent as the SAM material in the first SAM forming process, and subsequently, using a compound whose terminal has a double bond of C in the second SAM forming process. Thus, SAM may be formed in a predetermined region using the silane coupling agent in the first SAM forming process, and subsequently, in another region using the compound whose terminal has a double bond of C in the second SAM forming process, thereby obtaining a dense SAM. Alternatively, the first SAM material and the second SAM material may be supplied at once to form SAMs in respective regions having surface states corresponding to the first SAM material and the second SAM material. For example, by supplying both the silane coupling agent and the compound whose terminal has a double bond of C as SAM materials at once, SAMs may be formed in different regions. Thus, it is possible to form a denser SAM.

As described above, according to this embodiment, it is possible to form a dense SAM on a surface having a network structure of Si and O, thus applying the present disclosure to an application requiring a wear resistance such as a contamination preventing film.

### EXPERIMENT EXAMPLES

Next, experiment examples will be described.

### Experiment Example 1

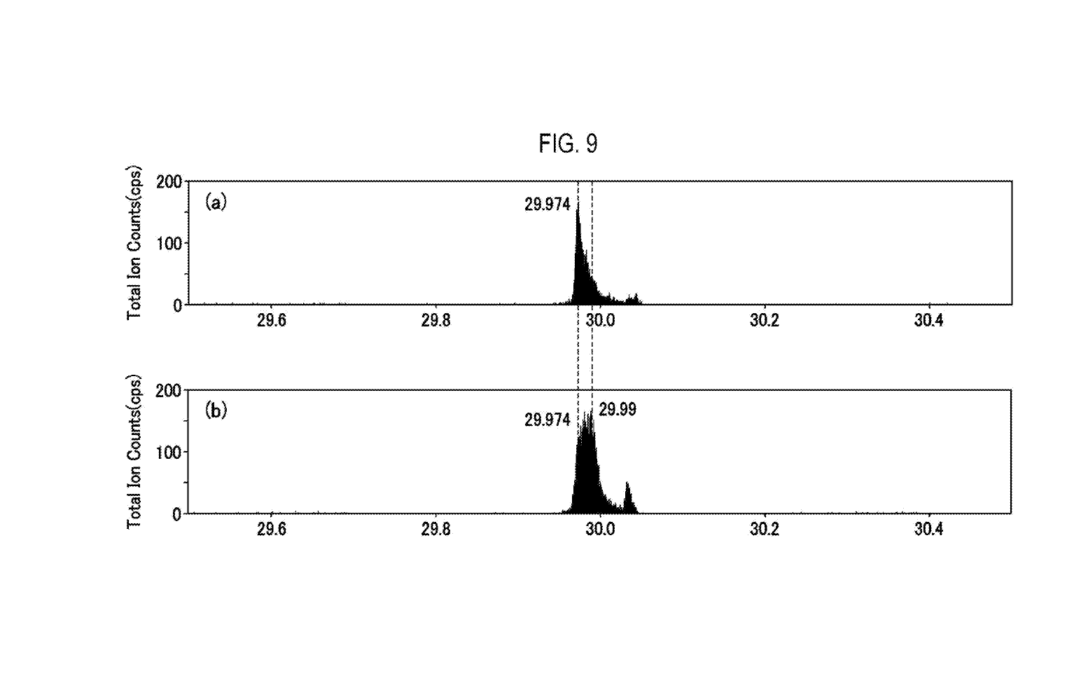

In experiment example 1, a SiO₂ substrate (glass substrate) was prepared as a substrate with a network structure of Si and O formed in at least a portion of a surface. The SiO₂ substrate was subjected to a surface treatment with plasma of an Ar/H₂ gas irradiated thereto. A surface state according to the presence or absence of the plasma treatment was checked by a TOF-SIMS mass spectrum. FIGS. 9A and 9B are views illustrating a state of the vicinity of mass number 30 of the TOF-SIMS mass spectrum in the check of the surface state, FIG. 9A showing a state where the plasma treatment is performed, and FIG. 9B showing a state where the plasma treatment is not performed. In the case that the plasma treatment is performed as shown in FIG. 9A, only a peak of 30Si as an isotope of Si has found, whereas in the case that the plasma treatment is not performed as shown in FIG. 9B, a signal of SiH₂ (29.99 amu) in addition to the 30Si has found. It can be seen from these spectrums that Si—H bonds are formed in the portion of the surface of the substrate by irradiating a hydrogen-containing plasma.

### Experiment Example 2

Next, the SAM was formed on the substrate subjected to a surface treatment of experiment example 1, through the use of a compound CH₂=CH—(OCF₂CF₂)ₙ whose terminal has a double bond of C as a SAM material (Sample A). —(OCF₂CF₂)ₙ is perfluoroether (PFE), which was used as the contamination preventing film. For comparison, the SAM was formed on a SiO₂ substrate which was subjected to a dilute hydrofluoric acid (DHF) cleaning without having to use the plasma treatment, through the use of (OCH₃)₃—Si—(OCF₂CF₂)ₙ which is a silane coupling agent as a SAM material (Sample B). (OCH₃)₃—Si—(OCF₂CF₂)ₙ contains PFE in molecules, which has been conventionally used to form the contamination preventing film.

For Sample A, since Si—H bonds were formed on the surface of the SiO₂ substrate, a film could be formed. In addition, for Sample B, the SAM was formed by reaction for a long time with water.

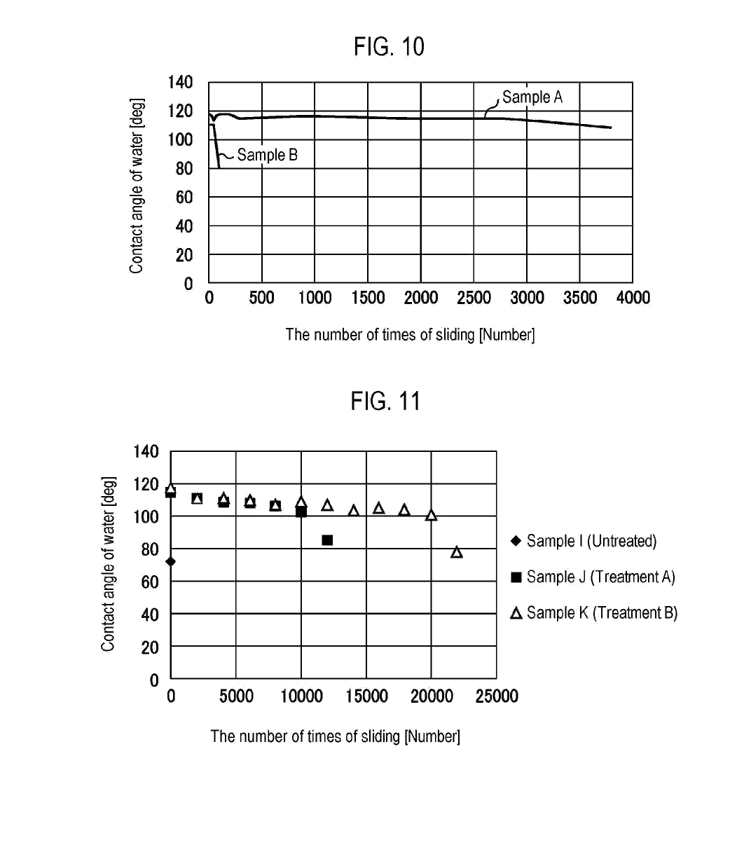

Subsequently, a wear durability test was conducted for Samples A and B. The wear durability test was conducted by a SW test in which the samples slide while being brought into contact with a steel wool carrying a weight. When a film is worn, an angle at which the film is in contact with water (hereinafter simply referred to as a “contact angle”) is lowered. The wear durability was evaluated based on a relationship between the number of times of sliding and the contact angle. A result of the evaluation is shown in FIG. 10. As shown in FIG. 10, Sample B manifested a lowered wear durability at a level of the number of times of sliding of less than 100 and the contact angle of 100 degrees C. or less. The reason for this is that controllability of the reaction of the silane coupling agent with SiO₂ is degraded due to water and the density of the film is degraded. In contrast, for Sample A, the contact angle was maintained at 100 deg or more even when the number of times of sliding exceeds 3500. Thus, Sample A manifested a film wear durability greatly higher than that of Sample B. This implies that the SAM having film density higher than Sample B was formed by performing the plasma treatment on the surface of the SiO₂ substrate to form Si—H bonds, and reacting the Si—H with the compound CH₂=CH—(OCF₂CF₂)ₙ whose terminal has a double bond of C.

### Experiment Example 3

In experiment example 3, Samples C to H were prepared by forming SAMs on SiO₂ substrates subjected to a variety of surface treatments, through the use of using Optool® (which is a silane coupling agent and is available from Daikin Industries. Ltd.) as a SAM material. Substrates used in preparing Samples C to H are as follows.
Sample C: SiO₂ substrate whose surface was cleaned by DHF,
Sample D: SiO₂ substrate subjected to a surface treatment with plasma generated by an Ar gas alone,
Sample E: SiO₂ substrate subjected to a surface treatment with plasma generated by an Ar gas and an H₂ gas,
Sample F: SiO₂ substrate subjected to a surface treatment with plasma generated by an Ar gas and an O₂ gas,
Sample G: SiO₂ substrate subjected to a surface treatment with plasma generated by an Ar gas, an H₂ gas and an O₂ gas, and
Sample H: SiO₂ substrate subjected to a surface treatment with plasma generated by an Ar gas, an H₂ gas and an O₂ gas (in which a flow rate of the O₂ gas was increased compared with Sample G).

Table 1 is a brief summary as to a surface treatment for substrate, an initial contact angles and the results of the SW test as a wear durability test for Samples C to H.

As can be confirmed from Table 1, for Sample C whose surface was merely cleaned by DHF without having to use the plasma treatment, the initial contact angle is 20 deg so that the SAM was just slightly formed. For Sample D subjected to a surface treatment with plasma generated by an Ar gas alone, although the initial contact angle is 115 deg so that the SAM was formed, the number of times of sliding which is enough to maintain a contact angle of 100 deg or more in the SW test (hereinafter referred to as “the number of times of wear resistance sliding”) was 100. Thus, Sample D manifested a lowered wear durability, which implies that the film density of the SAM thus formed is low. For Sample E subjected to a surface treatment with plasma generated by an Ar gas and an H₂ gas, the initial contact angle was 115 deg and the number of times of wear resistance sliding in the SW test was at a low level of 1000, which is larger than that for Sample D. This implies that the film density of the SAM thus formed is not yet sufficient. For Sample F subjected to a surface treatment with plasma generated by an Ar gas and an O₂ gas, the number of times of wear resistance sliding in the SW test was 100 which is identical substantially to that in Sample D. In contrast, for Samples G and H subjected to a surface treatment with plasma generated by an Ar gas, an H₂ gas and an O₂ gas, the number of times of wear resistance sliding in the SW test at which a contact angle is 100 deg or less was 10000 or more. Thus, Samples G and H manifested a high level of wear durability, which implies that the SAM is formed at high film density. Among these, for Sample H in which a flow rate of the O₂ gas is increased compared with Sample G, the number of times of wear resistance sliding in the SW test was 20000 or more, which implies that the film density is particularly high.

TABLE 1

| | | Initial contact | SW test |
|---|---|---|---|
| | Surface treatment for substrate | angle (deg) | (times) |
| Sample C | Only cleaning by DHF | 20 | 0 |
| Sample D | Plasma generated by Ar alone | 115 | 100 |
| Sample E | Plasma generated by Ar/H₂ | 115 | 1000 |
| Sample F | Plasma generated by Ar/O₂ | 115 | 100 |
| Sample G | Plasma generated by Ar/H₂/O₂ | 115 | 10000 |
| Sample H | Plasma generated by | 115 | 20000 |
| | Ar/H₂/O₂(in which flow rate of | | |
| | O₂ gas is increased compared | | |
| | with Sample G) | | |

### Experiment Example 4

Next, a wear durability test was conducted using the aforementioned SW test for: a sample (Sample I) prepared by forming the SAM on an SiO₂ substrate subjected merely to a DHF-based cleaning without having to use a plasma treatment, through the use of Optool® (which is a silane coupling agent and is available from Daikin Industries. Ltd.) as a SAM material; a sample (Sample J) prepared by forming the SAM on a SiO₂ substrate subjected to a plasma treatment (treatment A) using an Ar gas, an H₂ gas and an O₂ gas, under the condition that an internal pressure of a chamber is 6.7 Pa; and a sample (Sample K) prepared by forming the SAM on a SiO₂ substrate subjected to a plasma treatment (treatment B) using an Ar gas, an H₂ gas and an O₂ gas, under the condition that the internal pressure of the chamber is 100 Pa, unlike Sample A. Results of this wear durability test are shown in FIG. 11. As shown in FIG. 11, for Sample I not subjected to the plasma treatment, the initial contact angle was insufficient at a level of 70 deg. In contrast, for Samples J and K subjected to the plasma treatment using the Ar gas, the H₂ gas and the O₂ gas, the wear durability was very high, which implies that a dense SAM is obtained.

### <Other Applications>

The present disclosure is not limited to the above embodiments but may be modified in different ways. For example, although it has been illustrated in the above embodiments that the hydrogen-containing plasma treatment is mainly used as the surface treatment for substrate and the silane coupling agent and the compound whose terminal has a double bond of C are used as the film forming material, the surface treatment for substrate and the film forming material are not particularly limited as long as the surface of the substrate is in a state where bonding sites of the surface with a film forming material used exist at high density.

In addition, although it has been illustrated in the above embodiments that the SAM as the organic monomolecular film is formed on the SiO₂ substrate, a workpiece is not limited to the SiO₂ substrate as long as the workpiece has a surface having a network structure of Si and O. In addition, the type of the workpiece is not limited to the substrate. For example, by applying the present disclosure to a vessel-like workpiece, it is possible to manufacture a vessel whose surface is modified.

### EXPLANATION OF REFERENCE NUMERALS

100: organic monomolecular film forming apparatus, 200: surface treating part, 201: chamber, 202: substrate holder, 203: plasma generating part, 204: exhaust mechanism, 300: organic monomolecular film forming part, 301: chamber, 302: substrate holder, 303: SAM material supply system, 304: exhaust system, 400: substrate transfer part, 500: substrate loading/unloading part, 600: control part, S: substrate

What is claimed is:

1. A method for forming an organic monomolecular film on a surface of a workpiece with a network structure of silicon (Si) and oxygen (O) formed in at least a portion of the surface of the workpiece, comprising:
performing a surface treatment on the workpiece such that the surface of the workpiece has a state where bonding sites of an organic monomolecular film material to be used exist at high density; and
supplying the organic monomolecular film material to the workpiece subjected to the surface treatment and forming the organic monomolecular film on the surface of the workpiece,
wherein a region where bonding sites of a first organic monomolecular film material exist at high density and a region where bonding sites of a second organic monomolecular film material exist at high density are formed on the workpiece by the surface treatment, and
wherein a first organic monomolecular film is formed by supplying the first organic monomolecular film material, and subsequently, a second organic monomolecular film is formed by supplying the second organic monomolecular film material, so that the organic monomolecular film including the first organic monomolecular film and the second organic monomolecular film is formed.

2. The method of claim 1, wherein the organic monomolecular film is a self-assembled monolayer film.

3. The method of claim 2, wherein the surface treatment controls an amount of hydrogen (H) and oxygen (O) of the surface of the workpiece by a hydrogen-containing plasma, depending on the organic monomolecular film material to be used.

4. The method of claim 3, wherein the organic monomolecular film material is a compound whose terminal has a double bond of carbon (C), the surface treatment is performed using the plasma containing hydrogen and containing no oxygen so that an Si—H bond acting as a bonding site of the compound whose terminal has the double bond of C is formed on the surface of the workpiece by the plasma.

5. The method of claim 3, wherein the organic monomolecular film material is a silane coupling agent, the surface treatment is performed using the plasma containing hydrogen and oxygen so that an Si—H bond and an O—H bond acting as bonding sites of the silane coupling agent are formed on the surface of the workpiece by the plasma.

6. The method of claim 1, wherein the act of performing the surface treatment and the act of forming the organic monomolecular film are repeated plural times.

7. The method of claim 6, wherein a wet treatment is performed after the surface treatment is performed twice.

8. A method for forming an organic monomolecular film on a surface of a workpiece with a network structure of silicon (Si) and oxygen (O) formed in at least a portion of the surface of the workpiece, comprising:
performing a surface treatment on the workpiece such that the surface of the workpiece has a state where bonding sites of an organic monomolecular film material to be used exist at high density; and
supplying the organic monomolecular film material to the workpiece subjected to the surface treatment and forming the organic monomolecular film on the surface of the workpiece,
wherein a region where bonding sites of a first organic monomolecular film material exist at high density and a region where bonding sites of a second organic monomolecular film material exist at high density are formed on the workpiece by the surface treatment, and
wherein the organic monomolecular film is formed by simultaneously supplying the first organic monomolecular film material and the second organic monomolecular film material.

9. The method of claim 8, wherein the organic monomolecular film is a self-assembled monolayer film.

10. The method of claim 9, wherein the surface treatment controls an amount of hydrogen (H) and oxygen (O) of the surface of the workpiece by a hydrogen-containing plasma, depending on the organic monomolecular film material to be used.

11. The method of claim 10, wherein the organic monomolecular film material is a compound whose terminal has a double bond of carbon (C), the surface treatment is performed using the plasma containing hydrogen and containing no oxygen so that an Si—H bond acting as a bonding site of the compound whose terminal has the double bond of C is formed on the surface of the workpiece by the plasma.

12. The method of claim 10, wherein the organic monomolecular film material is a silane coupling agent, the surface treatment is performed using the plasma containing hydrogen and oxygen so that an Si—H bond and an O—H bond acting as bonding sites of the silane coupling agent are formed on the surface of the workpiece by the plasma.

13. The method of claim 8, wherein the act of performing the surface treatment and the act of forming the organic monomolecular film are repeated plural times.

14. The method of claim 13, wherein a wet treatment is performed after the surface treatment is performed twice.
